(19) United States
(12) Patent Application Publication
(10) Pub. No.: US 2024/0247362 A1
(43) Pub. Date: Jul. 25, 2024

(54) NOZZLE FOR A DISTRIBUTOR OF A MATERIAL DEPOSITION SOURCE, MATERIAL DEPOSITION SOURCE, VACUUM DEPOSITION SYSTEM AND METHOD FOR DEPOSITING MATERIAL

(71) Applicant: Applied Materials, Inc., Santa Clara, CA (US)

(72) Inventors: Julian AULBACH, Alzenau (DE); Andreas MÜLLER, Karlstein (DE); Harald WURSTER, Mömbris (DE); Andreas LOPP, Freigericht (DE); David Friedrich FREIHERR VON LINDENFELS, Obertshausen (DE); Takashi ANJIKI, Aschaffenburg (JP)

(21) Appl. No.: 18/558,817

(22) PCT Filed: May 21, 2021
(86) PCT No.: PCT/IB2021/054422

§ 371 Date: Nov. 3, 2023

(51) Int. Cl. C23C 14/24; C23C 14/12

(52) U.S. Cl. CPC C23C 14/243; C23C 14/12

(57) ABSTRACT

A nozzle for an evaporated material distributor is described. The nozzle includes a nozzle inlet for receiving evaporated material; a nozzle outlet; and a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

### TECHNICAL FIELD

Embodiments of the present disclosure relate to a nozzle for a material deposition source, a material distributor, a vacuum deposition system and a method for depositing material on a substrate. Embodiments of the present disclosure particularly relate to a nozzle for guiding evaporated material to a vacuum chamber of a vacuum deposition system, a material deposition source including a nozzle for guiding evaporated material to a vacuum chamber, and a method for depositing a material on a substrate in a vacuum chamber.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not use a back light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are deposited on a substrate in such a manner as to form a matrix display panel having individually energizable pixels. The OLED is generally placed between two glass panels, and the edges of the glass panels are sealed to encapsulate the OLED therein.

There are many challenges encountered in the manufacture of such display devices. OLED displays or OLED lighting applications include a stack of several organic materials, which are for example evaporated in a vacuum. The organic materials are deposited in a subsequent manner through shadow masks. For the fabrication of OLED stacks with high efficiency, the co-deposition or co-evaporation of two or more materials, e.g. host and dopant, leading to mixed/doped layers is beneficial. Further, it has to be considered that there are several process conditions for the evaporation of the very sensitive organic materials.

For evaporating and depositing a material on a substrate, the material is heated until the material evaporates. Pipes guide the evaporated material to the substrates through outlets or nozzles. In the past years, the precision of the deposition process has been increased, e.g. for being able to provide smaller and smaller pixel sizes. In some processes, masks are used for defining the pixels when the evaporated material passes through the mask openings. However, shadowing effects of a mask, the spread of the evaporated material, and the like, make it difficult to further increase the precision and the predictability of the evaporation process.

For example, document US 2016/0201195 describes a nozzle with a second injection part coupled with a first injection part, and being configured to correct the directionality of particles which are diffusely reflected at the outlet of the first injection part. The injected deposition material has an improved directionality by using the change of directionality of deposition material from the diffused reflection at the inner surface of the first injection part and the inner surface of the second injection part, respectively, by respectively controlling the surface roughness of the inner surface of the first injection part and the inner surface of the second injection part. Document JP2004079541 shows nozzles with a plurality of different shapes. A nozzle is positioned to allow directional delivery of a formulation and to adjust the flow rate of a formulation. Document WO 2018/054472 describes a nozzle, wherein a shadowing effect due to a mask provided in front of the substrate can be reduced. An aperture angle continuously increases up to the nozzle outlet. The aperture angle α at the nozzle outlet is referred to as exit aperture angle de and is described to be particularly α_{E}>40°. Previous attempts to improve an angular distribution of evaporated material by a nozzle focused on the direction of particles released from a surface of the nozzle. Further improvements of an angular distribution of evaporated material is beneficial.

In view of the above, embodiments described herein provide an improved nozzle, an improved material deposition source, an improved vacuum deposition system, and an improved method for depositing material on a substrate.

### SUMMARY

In light of the above, a nozzle, a material deposition source, a vacuum deposition system, and a method for depositing a material on a substrate are provided. Further advantages, features, aspects and details are apparent from the dependent claims, the description and drawings.

According to one embodiment, a nozzle for an evaporated material distributor is provided. The nozzle includes a nozzle inlet for receiving evaporated material; a nozzle outlet; and a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

According to one embodiment, a material deposition source for depositing a material on a substrate in a vacuum deposition chamber is provided. The material deposition source includes a distributor in fluid communication with a material source and at least one nozzle according to any of the embodiments described herein. Particularly, the nozzle includes a nozzle inlet for receiving evaporated material; a nozzle outlet; and a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

According to one embodiment, a vacuum deposition system is provided. The system includes a vacuum deposition chamber; and a material deposition source according to any the embodiments described herein. Particularly, the material deposition source includes a distributor in fluid communication with a material source and at least one nozzle according to any of the embodiments described herein. Particularly, the nozzle includes a nozzle inlet for receiving evaporated material; a nozzle outlet; and a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

According to one embodiment, a method for depositing a material on a substrate in a vacuum deposition chamber is provided. The method includes evaporating a material to be deposited; guiding the evaporated material to a distributor; and guiding the evaporated material through a plurality of nozzles according to any the embodiments described herein. Particularly, the nozzle includes a nozzle inlet for receiving evaporated material; a nozzle outlet; and a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Embodiments are depicted in the drawings and are detailed in the description which follows.

FIG. 1 shows a schematic cross-sectional view of a nozzle according to embodiments described herein for being connected to a distributor for guiding evaporated material from a material source into a vacuum chamber;

FIG. 2 shows graphs comparing the angular distribution of nozzles according to embodiments of the present disclosure and other nozzles;

FIG. 3 shows a schematic side view of a material deposition source according to further embodiments described herein;

FIG. 4 shows a vacuum deposition system according to embodiments described herein;

FIGS. 5A and 5B show schematic views of a distributor having nozzles according to embodiments described herein; and

FIG. 6 shows a flow chart of a method for depositing material on a substrate according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment applies to a corresponding part or aspect in another embodiment as well.

In the present disclosure, a “material source” or “material deposition source” (the terms may be used synonymously herein) may be understood as an assembly providing a material to be deposited on a substrate. In particular, the material deposition source may be configured to deposit material on a substrate in a vacuum chamber, such as a vacuum deposition chamber of a vacuum deposition system. According to some embodiments, the material deposition source may be an evaporation source. For instance, the material deposition source may include an evaporator or a crucible, which evaporates the material to be deposited on the substrate, and a distributor, e.g. a distribution pipe or one or more point sources which can be arranged along a vertical axis. The distributor is configured to release the evaporated material in a direction towards the substrate, e.g. through one or more outlets or one or more nozzles as described herein. A crucible may be understood as a device or a reservoir providing or containing the material to be evaporated. The crucible may be in fluid communication with a distributor. In one example, the crucible may be a crucible for evaporating organic materials, e.g. organic materials having an evaporation temperature of about 100° ° C. to about 600° C.

According to some embodiments described herein, a “distributor” may be understood as a distribution pipe for guiding and distributing the evaporated material. In particular, the distribution pipe may guide the evaporated material from an evaporator to one or more outlets (such as nozzles or openings) in the distribution pipe. For instance, the distribution pipe can be a linear distribution pipe extending in a first, especially longitudinal, direction. In some embodiments, the linear distribution pipe includes a pipe having the shape of a cylinder, wherein the cylinder may have a circular, a triangular or square-like bottom shape or any other suitable bottom shape.

In the present disclosure, a “nozzle” as referred to herein may be understood as a device for guiding a fluid, especially for controlling the direction or characteristics of a fluid (such as the rate of flow, speed, shape, and/or the pressure of the fluid that emerges from the nozzle). According to some embodiments described herein, a nozzle may be a device for guiding or directing a vapor, such as a vapor of an evaporated material to be deposited on a substrate. According to some embodiments, a nozzle may be part of a distributor, e.g. a distribution pipe. Additionally or alternatively, a nozzle as described herein may be connectable or connected to the distributor providing evaporated material and may receive evaporated material from the distributor.

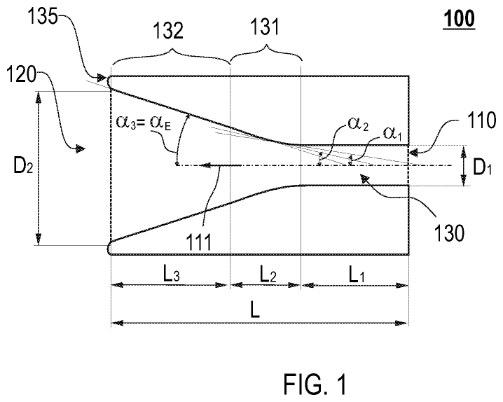

FIG. 1 shows examples of a nozzle 100 according to embodiments described herein for being connected to a distributor for guiding evaporated material from a material source into a vacuum chamber. The nozzle 100 includes a nozzle inlet 110, a nozzle outlet 120, and a nozzle passage 130 between the nozzle inlet 110 and the nozzle outlet 120. According to some embodiments, the evaporated material coming from the material source (such as a crucible) is guided into a distributor as described herein and enters the nozzle through the nozzle inlet 110. The evaporated material then passes through the nozzle passage 130 and exits the nozzle at the nozzle outlet 120. The flow direction 111 of the evaporated material can be described as being from the nozzle inlet 110 to the nozzle outlet 120. With exemplary reference to FIG. 1, according to embodiments of the nozzle as described herein, the nozzle passage 130 comprises a first passage portion, a second passage portion and a third passage portion. The nozzle portions are provided in this order, such that the second nozzle portion is between the first nozzle portion and the third nozzle portion. The first nozzle portion is at the nozzle inlet and the third nozzle portion is at the nozzle outlet.

According to an embodiment of the present disclosure, a nozzle for an evaporated material distributor is provided. The nozzle includes a nozzle inlet for receiving the evaporated material and a nozzle outlet. The nozzle includes a nozzle passage extending between the nozzle inlet and the nozzle outlet having a first passage portion, a second passage portion and a third passage portion, the second passage portion having an aperture angle which continuously increases in the direction from the nozzle inlet 110 to the nozzle outlet 120 and the third passage portion having an essentially constant aperture angle.

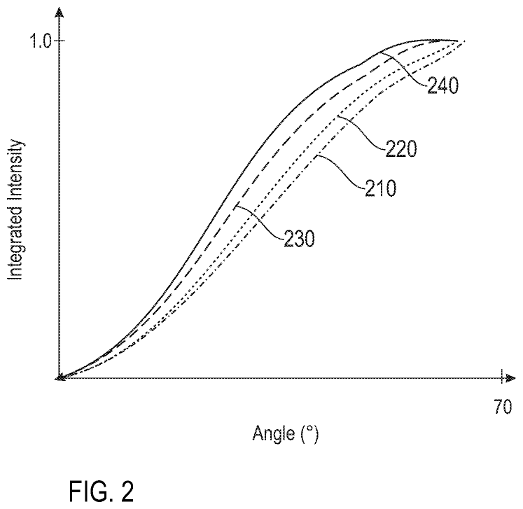

Embodiments of the present disclosure provide an improved directionality of the materials to be evaporated as shown in FIG. 2. According to some embodiments, which can be combined with other embodiments described herein, the nozzle shown in FIG. 1 may have a rotational symmetric shape. Previous nozzle designs as described in the background section emphasized on the correction of the directionality of particles which are diffusely reflected at the outlet of an injection part. Inventors have found that additionally the receiving characteristic of inner surfaces of the nozzle have a stronger influence than previously anticipated. Accordingly, embodiments provide a first passage portion, a second passage portion and a third passage portion to provide an improved directionality of materials to be evaporated while considering the emission characteristic of particles adhering to an inner surface as well as a receiving characteristic of an inner surface of a nozzle passage. A receiving characteristic is herein understood as the capability of a nozzle to adsorb or receive particles on an inner surface of a nozzle that deviate from a beneficial directionality of the evaporated material.

Accordingly, in addition to the second passage portion 131 which continuously increases in the direction from the nozzle inlet 110 to the nozzle outlet 120, a third passage portion 132 having an essentially constant aperture angle is provided. According to some embodiments, which can be combined with other embodiments described herein, the first nozzle passage has an aperture angle of essentially 0°. Further, the aperture angle of the nozzle passage continuously increases in the second passage portion up to an angle of α≥25°. This is illustrated by angles α1 and α2 in FIG. 1, wherein the aperture angle increases up to an aperture angle α3. Particularly, the aperture angle increases up to an aperture angle of α<40°. More particularly, according to some embodiments, which can be combined with other embodiments of the present disclosure, the aperture angle increases up to an aperture angle of α<36°.

According to embodiments of the present disclosure, the aperture angle α is essentially constant in the third passage portion. Essentially constant as described herein is understood to have a constant aperture angle with a deviation from being constant of +−3°. According to some embodiments, which can be combined with other embodiments described herein, the addition of the third passage portion increases the length L of the nozzle passage to be 25 mm or above.

According to some embodiments, a length ratio along the direction from the nozzle inlet to the nozzle outlet of the second passage portion and the third passage portion is from 1:2 to 2:1. The direction of the nozzle as referred to herein is understood as a main direction or a flow direction of the nozzle and is, for example, extending along an axis of the first passage portion, i.e. a central axis of the first passage portion.

According to some embodiments, which can be combined with other embodiments described herein, the nozzle passage includes a tangential junction between the second passage portion and the third passage portion. Additionally or alternatively, a tangential junction is provided between the first passage portion and the second passage portion. A tangential junction is understood as a continuous function for the aperture angle along the direction of the nozzle passage.

According to some embodiments, which can be combined with other embodiments described herein, the inner diameter D1 of first passage portion is 12 mm or below. Additionally or alternatively, the inner diameter D1 of first passage portion may be 3 mm or above.

Embodiments of the present disclosure relate to a masked deposition, e.g. for OLED display manufacturing, or a co-evaporation of materials, such as hosts and dopants for OLED display manufacturing. The nozzle can include a material adapted for an evaporated organic material having a temperature between about 100° C. and about 600° C.

According to an embodiment of the present disclosure, a nozzle as described herein may be used for depositing a material on a substrate in a vacuum deposition chamber, particularly for producing an organic light emitting diode.

FIG. 2 shows the angular distribution of various nozzle designs. The curve 210 shows the integrated intensity as a function of the angle for a standard nozzle. The curve 220 shows the integrated intensity as a function of the angle for a nozzle as described e.g. in document WO 2018/054472. The curve 230 shows the integrated intensity as a function of the angle for a nozzle according to embodiments of the present disclosure having a first inner diameter D1 of the first passage portion. The curve 240 shows the integrated intensity as a function of the angle for a nozzle according to embodiments of the present disclosure having a second inner diameter D1 of the first passage portion, wherein the second inner diameter is smaller than the first inner diameter.

It can be seen that the integrated intensity increases for a given angular distribution value. For example, the integrated intensity for a 40° focus can be above 79% for the nozzle having the curve 240.

Accordingly, by utilizing or providing a nozzle according to embodiments described herein for depositing evaporated material onto a substrate, a shadowing effect due to a mask provided in front of the substrate can be reduced, which is described in more detail with reference to FIG. 2 above. Further, for co-evaporation, for example, when utilizing a common metal mask (CMM) or another deposition process, the material mixing on the substrate can be improved.

Embodiments of the present disclosure may relate to masked deposition. A fine metal mask (FMM) may be used for some processes during display manufacturing, wherein the mask includes a pattern defining pixels of a display. For some processes during device manufacturing, a CMM may be used, i.e. a mask having a large opening for a display. According to yet further implementations, which can be combined with other embodiments described herein, co-evaporation can be utilized for CMM processes and for FMM processes. For co-evaporation, different materials are deposited on a substrate, and particularly are simultaneously deposited on a substrate. For example, a material deposition source can include two or more, for example, three material deposition sources next to each other. For example, one deposition source may deposit a host material and one deposition source may simultaneously deposit a dopant material. Material mixing occurs on the substrate or shortly before the material reaches the substrate. The improved directionality enhances material mixing and/or enhances pixel resolution based on reduced shadowing effects.

For example, if masks are used for depositing material on a substrate, such as in an OLED production system, the mask may be a pixel mask with pixel openings having the size of about 50 μm×50 μm, or even below, such as a pixel opening with a dimension of the cross section (e.g. the minimum dimension of a cross section) of about 30 μm or less, or about 20 μm. In one example, the pixel mask may have a thickness of about 40 μm. Considering the thickness of the mask and the size of the pixel openings, a shadowing effect may appear, where the walls of the pixel openings in the mask shadow the pixel opening. The nozzle according to embodiments described herein may help in reducing the shadowing effect such that displays with a high pixel density (dpi), particularly Ultra High Definition (UHD) displays (e.g. UHD-OLED displays), can be produced.

According to embodiments described herein, the nozzle passage 130 includes a passage wall surrounding a passage channel. The passage wall surrounds the nozzle passage or the passage channel, i.e. surrounds the passage channel over the circumference of the passage channel. Accordingly, the passage wall leaves the nozzle passage 130 open at two ends, i.e. the nozzle inlet 110 and the nozzle outlet 120.

According to some embodiments, which can be combined with other embodiments described herein, the aperture angle (a) continuously increases in the flow direction within the second passage portion such that the diameter of the outlet section of the nozzle passage 130 continuously increases in a circular-segment-like manner in the second passage portion in the flow direction. The aperture angle (a) is essentially constant in the third passage portion. Accordingly, evaporated material may be more likely to adhere in the third passage portion and will be released with an improved angular distribution.

According to some embodiments, which can be combined with other embodiments described herein, the nozzle is configured for guiding an evaporated organic material having a temperature between about 100° C. and about 600° ° C. to the vacuum chamber. Further, the nozzle can be configured for a mass flow of less than 0.5 sccm. For instance, the mass flow within a nozzle according to embodiments described herein may particularly be only a fractional amount of 0.8 sccm, and more particularly below 0.25 sccm. In one example, the mass flow in a nozzle according to embodiments described herein may be less than 0.1 sccm, such as less than 0.05, particularly less than 0.03 sccm, more particularly less than 0.02 sccm.

Additionally or alternatively, the nozzle passage has a minimum dimension, for example, a diameter D1 of the first passage portion of less than 12 mm.

According to embodiments, which can be combined with other embodiments described herein, the nozzle may include a nozzle passage having sections of different length. For instance, FIG. 1 shows a nozzle 100 with a first passage portion having a first length L1, a second passage portion having a second length L2, and a third passage portion having a second length L3. In particular, a length of a passage portion is to be understood as the dimension of the nozzle section along the length direction of the nozzle, or along the main flow direction, i.e. the flow direction 111 exemplarily shown in FIG. 1, of the evaporated material in the nozzle. The first passage portion of the nozzle provides a first diameter, e.g. the inlet diameter D1. The second passage portion of the nozzle provides a continuously increasing diameter, which continuously increases from the first diameter to a second diameter. The third passage portion has an essentially constant aperture angle)(>10°, wherein the diameter increases up to, e.g. the outlet diameter D2. In other words, according to some embodiments, which may be combined with other embodiments described herein, the first passage portion of the nozzle may include the nozzle inlet and the third passage portion of the nozzle may include the nozzle outlet. The second passage portion is between the first passage portion and the third passage portion.

Further, the high directionality which can be achieved by using a nozzle according to embodiments described herein results in an improved utilization of the evaporated material, because more of the evaporated material actually reaches the substrate.

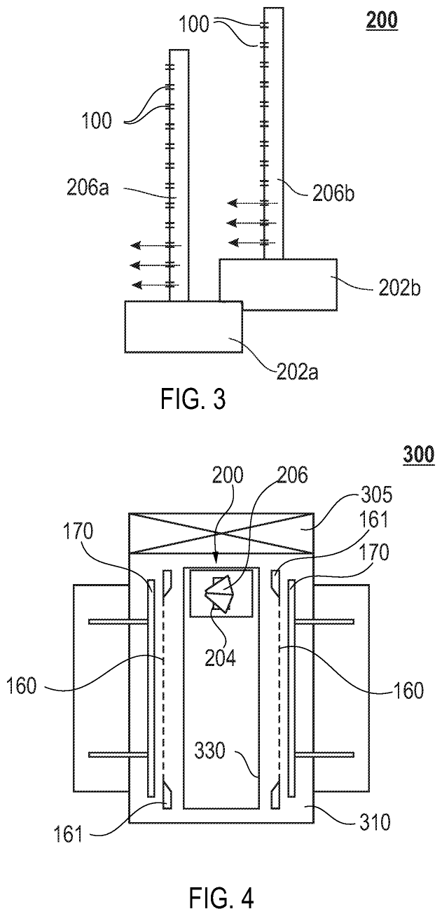

With exemplary reference to FIG. 3, a material deposition source 200 for depositing a material on a substrate in a vacuum deposition chamber is described. The material deposition source 200 typically includes a distributor, for example two or more distribution assemblies, such as a first distributor 206a and a second distributor 206b, e.g. distribution pipes. Each distributor can be in fluid communication with a material source (e.g. an evaporator or a crucible) providing the material to the distributor. The material deposition source further includes a plurality of nozzles according to embodiments described herein.

According to some embodiments, which can be combined with other embodiments described herein, the nozzles of the distribution pipe may be adapted for releasing the evaporated material in a direction different from the length direction of the distribution pipe, such as a direction being substantially perpendicular to the length direction of the distribution pipe. According to some embodiments, the nozzles are arranged to have a main evaporation direction (also referred to as flow direction 111 in FIG. 1) being horizontal+−20°. According to some specific embodiments, the evaporation direction can be oriented slightly upward, e.g. to be in a range from horizontal to 15° upward, such as 3° to 7° upward. Correspondingly, the substrate can be slightly inclined to be substantially perpendicular to the evaporation direction. Undesired particle generation can be reduced. However, the nozzle and the material deposition source according to embodiments described herein may also be used in a vacuum deposition system, which is configured for depositing material on a horizontally oriented substrate.

In some implementations, the length of the distribution pipe corresponds at least to the height of the substrate to be deposited in the deposition system. The length of the distribution pipe will be longer than the height of the substrate to be deposited, at least by 10% or even 20%. A uniform deposition at the upper end of the substrate and/or the lower end of the substrate can be provided. According to some embodiments, which can be combined with other embodiments described herein, the length of the distribution pipe can be 1.3 m or above, for example 2.5 m or above. According to a configuration, as shown in FIG. 3, the material source, such as a first evaporator 202a and a second evaporator 202b can be provided at a lower end of the distribution pipe. Alternatively, the material source may be provided essentially at a center along the length direction. The organic material is evaporated in the evaporation crucible. The vapor of organic material enters the distribution pipe and is guided essentially sideways through the plurality of nozzles in the distribution pipe, e.g. towards an essentially vertical substrate.

As described herein, the distributor can be a distribution pipe having a hollow cylinder. The term cylinder can be understood as having a circular bottom shape, a circular upper shape and a curved surface area or shell connecting the upper circle and the small lower circle. According to further additional or alternative embodiments, which can be combined with other embodiments described herein, the term cylinder can further be understood in the mathematical sense as having an arbitrary bottom shape, an identical upper shape and a curved surface area or shell connecting the upper shape and the lower shape. Accordingly, the cylinder does not necessarily need to have a circular cross-section. Instead, the base surface and the upper surface can have a shape different from a circle. According to some embodiments, which can be combined with other embodiments described herein, the cross-section may be triangular, e.g. with rounded edges. Thus, nozzles of neighboring pipes for co-evaporation can be closer together, e.g. 70 mm or below.

According to some embodiments, which can be combined with other embodiments described herein, at least one nozzle 100 is in fluid communication with the linear distribution pipe. Further, the crucible can be in fluid communication with a distribution pipe, and the distribution pipe is in fluid communication with the at least one nozzle.

With exemplary reference to FIG. 4, embodiments of a vacuum deposition system 300 are described. According to embodiments, which can be combined with any other embodiments described herein, the vacuum deposition system 300 includes a vacuum deposition chamber 310 and a material deposition source 200 as exemplarily described above with reference to FIG. 3. The vacuum deposition system further includes a substrate support for supporting the substrate during deposition.

In particular, FIG. 4 shows a vacuum deposition system 300 in which a nozzle 100 and a material deposition source 200 according to embodiments described herein may be used. The vacuum deposition system 300 includes a material deposition source 200 in a position in a vacuum deposition chamber 310. The material deposition source 200 may be configured for a translational movement and a rotation around an axis, particularly an essentially vertical axis. The material deposition source 200 has one or more material sources 204, particularly one or more evaporation crucibles, and one or more distribution assemblies 206, particularly one or more distribution pipes. For instance, in FIG. 4, two evaporation crucibles and two distribution pipes are shown. Further, two substrates 170 are provided in the vacuum deposition chamber 310. Typically, a mask 160 for masking of the layer deposition on the substrate can be provided between the substrate and the material deposition source 200.

According to embodiments described herein, the substrates are coated with organic material in an essentially vertical position. The view shown in FIG. 4 is a top view of a system including the material deposition source 200. Typically, the distributor is configured to be a distribution pipe having a vapor distribution showerhead, particularly a linear vapor distribution showerhead. The distribution pipe provides a line source extending essentially vertically. According to embodiments described herein, which can be combined with other embodiments described herein, essentially vertically is understood particularly when referring to the substrate orientation, to allow for a deviation from the vertical direction of 20° or below, e.g. of 10° or below. The deviation can be provided for example because a substrate support with some deviation from the vertical orientation might result in a more stable substrate position. The surface of the substrates is typically coated by a line source extending in one direction corresponding to one substrate dimension, e.g. the vertical substrate dimension, and a translational movement along the other direction corresponding to the other substrate dimension, e.g. the horizontal substrate dimension. According to other embodiments, the deposition system may be a deposition system for depositing material on an essentially horizontally oriented substrate. For instance, coating of a substrate in a deposition system may be performed in an up or down direction.

With exemplary reference to FIG. 4, the material deposition source 200 may be configured to be movable within the vacuum deposition chamber 310, such as by a rotational or a translational movement. For instance, the material source shown in the example of FIG. 4 is arranged on a track 330, e.g. a looped track or linear guide. Typically, the track or the linear guide is configured for the translational movement of the material deposition source. According to different embodiments, which can be combined with other embodiments described herein, a drive for the translational or rotational movement can be provided in the material deposition source within the vacuum chamber or a combination thereof. Further, in the exemplary embodiment of FIG. 4, a valve 305, for example a gate valve, is shown. The valve 305 may allow for a vacuum seal to an adjacent vacuum chamber (not shown in FIG. 4). The valve can be opened for transport of a substrate 170 or a mask 160 into the vacuum deposition chamber 310 or out of the vacuum deposition chamber 310.

As exemplarily shown in FIG. 4, according to embodiments which can be combined with any other embodiment described herein, two substrates 170 can be supported on respective transportation tracks within the vacuum chamber. Further, two tracks for providing masks 160 thereon can be provided. Accordingly, during coating the substrates can be masked by respective masks. According to some embodiments, the masks 160, i.e. a first mask corresponding to a first substrate and a second mask corresponding to a second substrate, are provided in a mask frame 161 to hold the mask 160 in a predetermined position. For instance, the first mask and the second mask may be pixel masks.

It is to be understood that the described material deposition source and the vacuum deposition system may be used for various applications, including applications for OLED device manufacturing including processing methods, wherein two or more organic materials are evaporated simultaneously. Accordingly, as for example shown in FIG. 4, two or more distribution pipes and corresponding evaporation crucibles can be provided next to each other. Although the embodiment shown in FIG. 4 provides a deposition system with a movable source, the skilled person may understand that the above described embodiments may also be applied in deposition systems in which the substrate is moved during processing. For instance, the substrates to be coated may be guided and driven along a stationary material deposition source.

According to some embodiments, which can be combined with any other embodiment described herein, the vacuum deposition system is configured for large area substrates or substrate carriers supporting one or more substrates. For instance, the large area substrate may be used for display manufacturing and may be a glass or plastic substrate. In particular, substrates as described herein shall embrace substrates which are typically used for an LCD (Liquid Crystal Display), a PDP (Plasma Display Panel), an OLED display and the like. For example, a “large area substrate” can have a main surface with an area of 0.5 m² or larger, particularly of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace inflexible substrates, e.g., glass plates and metal plates. However, the present disclosure is not limited thereto, and the term “substrate” can also embrace flexible substrates such as a web or a foil. According to some embodiments, the substrate can be made of any material suitable for material deposition. For instance, the substrate can be made of a material selected from the group consisting of glass (for instance soda-lime glass, borosilicate glass etc.), metal, polymer, ceramic, compound materials, carbon fiber materials, mica or any other material or combination of materials which can be coated by a deposition process. For example, the substrate can have a thickness of 0.1 mm to 1.8 mm, such as 0.7 mm, 0.5 mm or 0.3 mm. In some implementations, the thickness of the substrate may be 50 μm or more and/or 700 μm or less. Handling of thin substrates with a thickness of a few microns, e.g. 8 μm or more and 50 μm or less, may be challenging.

According to some embodiments, which may be combined with other embodiments described herein, a material source, an evaporator or a crucible as described herein may be configured to receive organic material to be evaporated and to evaporate the organic material. According to some embodiments, the material to be evaporated may include at least one of ITO, NPD, Alq3, Quinacridone, Mg/AG, starburst materials, and the like. As described herein, the nozzle may be configured for guiding evaporated organic material to the vacuum chamber. For instance, the material of the nozzle may be adapted for evaporated organic material having a temperature of about 100° ° C. to about 600° C. For instance, in some embodiments, the nozzle may include a material having a thermal conductivity larger than 21 W/mK and/or a material being chemically inert to evaporated organic material. According to some embodiments, the nozzle may include at least one of Cu, Ta, Ti, Nb, DLC, and graphite or may include a coating of the passage wall with one of the named materials.

In one example, the pressure in the distributor, particularly the distribution pipe, may be between about 10-2 mbar to about 10-5 mbar, or between about 10-2 to about 10-3 mbar. According to some embodiments, the vacuum chamber may provide a pressure of about 10-5 to about 10-7 mbar.

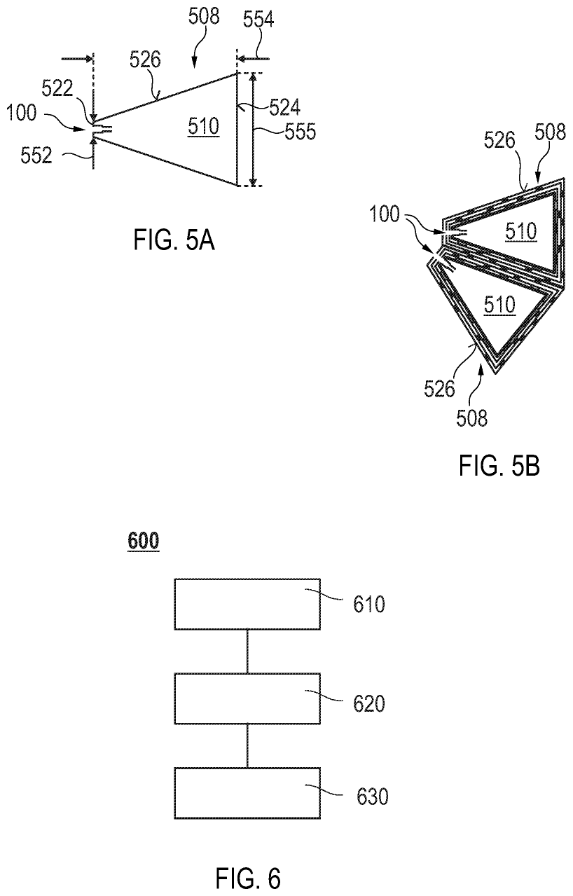

With exemplary reference to FIG. 5A, according to some embodiments which may be combined with other embodiments described herein, the distribution pipe of the material deposition source may have a substantially triangular cross-section. The distribution pipe 508 has walls 522, 526, and 524, which surround an inner hollow space 510. The wall 522 is provided at an outlet side of the distribution pipe, at which a nozzle 100 or several nozzles are provided. The nozzles may be nozzles as described with respect to FIG. 1. Further, and not limited to the embodiment shown in FIG. 5A, the nozzle may be connectable (such as screwable) to the distribution pipe or may be integrally formed in the distribution pipe. The cross-section of the distribution pipe can be described as being essentially triangular. A triangular shape of the distribution pipe makes it possible to bring the outlets, e.g. nozzles, of neighboring distribution pipes as close as possible to each other. This allows for achieving an improved mixture of different materials from different distribution pipes, e.g. for the case of the co-evaporation of two, three or even more different materials.

The width of the outlet side of the distribution pipe, e.g. the dimension of the wall 522 in the cross-section shown in FIG. 5A, is indicated by arrow 552. Further, the other dimensions of the cross-section of the distribution pipe 508 are indicated by arrow 554 and arrow 555. According to embodiments described herein, the width of the outlet side of the distribution pipe is 30% or less of the maximum dimension of the cross-section, e.g. 30% of the larger dimension of the dimensions indicated by arrow 555. In light of the dimensions and the shape of the distribution pipe, the nozzles 100 of neighboring distribution pipes can be provided at a smaller distance. The smaller distance improves mixing of organic materials, which are evaporated next to each other.

FIG. 5B shows an embodiment in which two distribution pipes are provided next to each other. Accordingly, a material deposition source having two distribution pipes as shown in FIG. 5B can evaporate two organic materials next to each other. As shown in FIG. 5B, the shape of the cross-section of the distribution pipes allows for placing nozzles of neighboring distribution pipes close to each other. According to some embodiments, which can be combined with other embodiments described herein, a first nozzle of the first distribution pipe and a second nozzle of the second distribution pipe can have a distance of 70 mm or below, such as from 5 mm to 60 mm. According to some embodiments, three distribution pipes may be provided next to each other.

In view of the above, it is to be understood that the embodiments of the material deposition source and the embodiments of the vacuum deposition system herein are in particular beneficial for the deposition of organic materials, e.g. for OLED display manufacturing on large area substrates.

With exemplary reference to the flow chart in FIG. 6, embodiments of a method 600 for depositing material on a substrate 170 in a vacuum deposition chamber 310 are described. In particular, the method 600 includes evaporating 610 a material to be deposited in a crucible. In particular, the material is heated in the crucible. For instance, the material to be deposited may be an organic material for forming an OLED device. The crucible may be heated depending on the evaporation temperature of the material. In some examples, the material is heated up to 600° C., such as heated up to a temperature between about 100° C. and 600° C. According to some embodiments, the crucible stands in fluid communication with a distribution pipe.

Further, the method 600 includes providing 620 the evaporated material to a distributor being in fluid communication with the crucible. In some embodiments, the distribution pipe is at a first pressure level, wherein the first pressure level may for instance be typically between about 10-2 mbar to 10-5 mbar, more typically between about 10-2 mbar and 10-3 mbar. According to some embodiments, the vacuum deposition chamber is at a second pressure level, which may for instance be between about 10-5 to 10-7 mbar. In some embodiments, the material deposition source is configured to move the evaporated material using the vapor pressure of the evaporated material in a vacuum, i.e. the evaporated material is driven to the distribution pipe (and/or through the distribution pipe) by the evaporation pressure only (e.g. by the pressure originating from the evaporation of the material). For instance, no further elements (such as fans, pumps, or the like) are used for driving the evaporated material to and through the distribution pipe.

Additionally, the method 600 includes guiding 630 the evaporated material through a nozzle having a nozzle passage extending from a nozzle inlet to a nozzle outlet and according to embodiments of the present disclosure. Typically, guiding 630 the evaporated material through the nozzle further includes guiding the evaporated material through an outlet section of the nozzle passage having a first passage portion, a second passage portion and a third passage portion, the second passage portion having an aperture angle which continuously increases in the direction from the nozzle inlet 110 to the nozzle outlet 120 and the third passage portion having an essentially constant aperture angle. In particular, guiding 630 the evaporated material through a nozzle passage may include guiding the evaporated material through a nozzle passage of a nozzle according to embodiments described herein, for instance as described with reference to FIG. 1.

Accordingly, in view of the above, the embodiments of the nozzle, the embodiments of the material deposition source, the embodiments of the vacuum deposition system, and the embodiments of the method for depositing a material on a substrate, provide for improved high resolution, particularly ultra-high resolution, display manufacturing, e.g. OLED-displays and/or may provide for an improved material mixing during co-evaporation. According to some embodiments, which can be combined with other embodiments described herein, the method for depositing according to embodiments of the present disclosure can be included in a method of manufacturing device, such as a display device or a semiconductor device. The display device may particularly be an OLED display device.

This written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A nozzle for an evaporated material distributor, the nozzle comprising:
a nozzle inlet for receiving evaporated material; a
nozzle outlet; and
a nozzle passage extending between the nozzle inlet and the nozzle outlet having a first passage portion, a second passage portion and a third passage portion, the second passage portion having an aperture angle which continuously increases in a direction from the nozzle inlet to the nozzle outlet and the third passage portion having an essentially constant aperture angle.

2. The nozzle according to claim 1, wherein the first passage portion has an aperture angle of essentially 0°.

3. The nozzle according to claim 1, wherein the aperture angle continuously increases in the second passage portion up to an angle of α≥25°.

4. The nozzle according to claim 2, wherein the aperture angle continuously increases in the second passage portion up to an angle of α<40°.

5. The nozzle according to claim 1, wherein a length ratio along the direction between the second passage portion and the third passage portion is from 1:2 to 2:1.

6. The nozzle according to claim 1, wherein the nozzle passage includes a tangential junction between the second passage portion and the third passage portion.

7. The nozzle according to claim 1, wherein an inner diameter of the first passage portion is 10 mm or below.

8. The nozzle according to claim 1, wherein the nozzle comprises a material adapted for an evaporated organic material having a temperature between about 100° C. and about 600° C.

9. Use of a nozzle according to claim 1 for depositing a material on a substrate in a vacuum deposition chamber.

10. A material deposition source for depositing a material on a substrate in a vacuum deposition chamber, comprising:
a distributor in fluid communication with a material source; and
at least one nozzle according to claim 1.

11. The material deposition source according to claim 10, wherein the material source is a crucible for evaporating material and wherein the distributor includes a linear distribution pipe.

12. A vacuum deposition system, comprising:
a vacuum deposition chamber; and
a material deposition source according to claim 10 in the vacuum deposition chamber.

13. A method for depositing a material on a substrate in a vacuum deposition chamber, comprising:
evaporating a material to be deposited;
guiding the evaporated material to a distributor; and
guiding the evaporated material through a plurality of nozzles according to claim 1.

14. The nozzle according to claim 5, wherein the nozzle passage includes a tangential junction between the second passage portion and the third passage portion.

15. The nozzle according to claim 5, wherein an inner diameter of the first passage portion is 10 mm or below.

16. The nozzle according to claim 6, wherein an inner diameter of the first passage portion is 10 mm or below.

17. The nozzle according to claim 5, wherein the nozzle comprises a material adapted for an evaporated organic material having a temperature between about 100° C. and about 600° C.

18. The nozzle according to claim 6, wherein the nozzle comprises a material adapted for an evaporated organic material having a temperature between about 100° C. and about 600° C.

19. The nozzle according to claim 1, wherein a main evaporation direction of the nozzle is an essentially horizontal direction.

20. The use of a nozzle according to claim 15, wherein the material is deposited on the substrate for producing an organic light emitting diode.
